(19) United States
(12) Patent Application Publication
(10) Pub. No.: US 2008/0220645 A1
(43) Pub. Date: Sep. 11, 2008

(54) METHOD FOR INTEGRATING AN INDICATOR LIGHT IN A CONNECTOR ASSEMBLY

(75) Inventor: Michael FELDMAN, Thornhill (CA)

Correspondence Address: PATENT ADMINISTRATOR;KATTEN MUCHIN ROSENMAN LLP, 1025 THOMAS JEFFERSON STREET, N.W., EAST LOBBY: SUITE 700, WASHINGTON, DC, 20007-5201, US

(73) Assignee: SANGOMA TECHNOLOGIES CORPORATION, Markham (CA)

(21) Appl. No.: 12/033,565

(22) Filed: Feb. 19, 2008

Related U.S. Application Data
(62) Division of application No. 11/548,832, filed on Oct. 12, 2006.

(51) Int. Cl. H01R 3/00; H05K 3/34

(52) U.S. Cl. 439/490; 29/832

(57) ABSTRACT

An apparatus and method for integrating an indicator light in a connector assembly. A connector is mounted on a first side of the circuit board and an LED is mounted on an opposing side of the circuit board such that the LED is configured to project light through a light transfer passage into the interior of the connector on the first side of the circuit board. The LED can be used to provide a visual indication of a configuration or status of a circuit associated with the connector. The visual indication illuminates the interior surface of the connector when it is empty or illuminates a light transmissible plug inserted into the connector such that the visual indication is visible external to the connector. The novel arrangement can reduce manufacturing costs and permit easier replacement of a defective LED without requiring the removal of the connector.

### CROSS-REFERENCE TO RELATED APPLICATIONS

The present application is a divisional of U.S. patent application Ser. No. 11/548,832, filed Oct. 12, 2006, the entire contents of which are hereby incorporated herein by reference.

### TECHNICAL FIELD

The present invention relates to transmission of visual indications through a printed circuit board connector on a printed circuit board and improvements thereto.

### BACKGROUND OF THE INVENTION

Electronic equipment such as telecommunications or networking equipment, typically requires interconnection with other devices. An example of such interconnections are the modular connector jacks used for telephone connections or Ethernet connections sometimes referred to as RJ-XX (“registered jacks”) in North America. It is often desirable to display status information related to each jack or its associated communication link. Prior art examples of such status indicators include light emitting diode (LED) indicators mounted on a panel adjacent to such modular jacks, mounting an LED on a printed circuit board and transmitting light from the LED to a position adjacent to the modular jack via a light pipe or incorporating such a light pipe into the housing of the modular jack. U.S. Pat. No. 6,241,550 to Laity et al. describes a connector system having a light guide extending between a light source on a circuit board and a receptacle of a connector. Possible disadvantages of prior art implementations using a light guide include increased costs for adding a light guide component, increased manufacturing costs for specialized connectors incorporating such light guides light pipes, and increased circuit board real estate requirements for designs incorporating light pipes. An example of such a prior art configuration is shown in FIG. 1.

U.S. Pat. No. 5,790,041 to Lee describes an apparatus and method for displaying network connection status on a jack panel. Lee describes an LED mounted adjacent to the jack where the jack overlies the LED on the printed circuit board. Possible disadvantages for such prior art designs include increased manufacturing costs. Such an arrangement typically requires a two-step manufacturing process wherein first the LED is mounted to the circuit board and second, the jack is mounted to the circuit board. Modern manufacturing techniques take advantage of the cost savings of surface mount technology which typically can not accommodate mounting a LED and an overlying connector jack in one process step. Another possible disadvantage is that if an LED is later determined to be defective, it is typically prohibitively expensive or difficult to remove and replace the LED underneath the connector jack. An example of such a prior art connector arrangement is shown in FIG. 2.

Accordingly, it remains highly desirable to provide an improved arrangement for providing visual indicators for electronic interconnection jacks.

### SUMMARY OF THE INVENTION

Accordingly, an aspect of the present invention provides an apparatus comprising a circuit board having a first side and a second side; a connector mounted on the first side of the circuit board, the connector having an interior in communication with a first opening configured to accept a plug; a light emitting device mounted on the second side of the circuit board; wherein the light emitting device is in optical communication with the interior of the connector such that when activated, the light emitting device is configured to project light into the interior, the light being visible external to the first opening.

In some embodiments, the connector is opaque.

In some embodiments, the light is visible external to the first opening of the connector when a light transmissible plug is operatively engaged in the connector.

In some embodiments, the circuit board further comprises a light transfer passage configured to permit light from the light emitting device to illuminate the interior of the connector.

In some embodiments, the light transfer passage is a hole.

In some embodiments, the light transfer passage is a light transmissible portion of the circuit board.

In some embodiments, the light transfer passage is a light pipe.

In some embodiments, the connector is overlying the light transfer passage.

In some embodiments, the connector is an RJ series jack.

In some embodiments, the circuit board is configured for surface mounting of the light emitting device.

In some embodiments, the circuit board is configured for surface mounting of the connector.

A further aspect of the present invention provides a circuit board comprising: a first side; a second side; a through-hole between the first side and the second side; a wiring pattern on the first side for electrically coupling to a connector having a housing, configured such that when the connector is electrically coupled to the circuit board, the housing overlies the through-hole on the first side; a wiring pattern on the second side for electrically coupling to a light emitting device, configured such that when the light emitting device is electrically coupled to the circuit board, the light emitting device overlies the through-hole on the second side, such that the light emitting device is in optical communication with an interior surface of the connector.

In some embodiments, the wiring pattern on the second side provides a first contact and a second contact for the light emitting device, such that the through-hole is located there between.

In some embodiments, the wiring pattern on the second side is configured for surface mounting of the light emitting device.

In some embodiments, the wiring pattern on the first side is configured for surface mounting of the connector.

In some embodiments, the light emitting device is a light emitting diode.

In some embodiments, the light emitting device comprises a plurality of light emitting diodes.

In some embodiments, the plurality of light emitting diodes comprises a red and a green light emitting diode.

In some embodiments, the circuit board is a circuit interface card for a PBX.

A further aspect of the present invention provides a method of preparing a circuit board assembly. The method comprising steps of: providing a printed circuit board having first and second opposed surfaces; providing a light transfer passage in the printed circuit board to extend between the first and second opposed surfaces; providing a connector having a housing, the housing having an interior region in communication with a first opening, the opening configured to accept a plug; locating the connector on the first opposed surface, such that the light transfer passage is in optical communication with the interior region; locating a light emitting device on the second opposed surface, such that the light emitting device is oriented to project light through the light transfer passage into the interior region; subjecting the printed circuit board to a reflow soldering process to operatively mount the light emitting device and the connector to the printed circuit board.

In some embodiments, the step of reflow soldering comprises infrared reflow soldering.

In other embodiments, the step of reflow soldering comprises vapor phase soldering.

In some embodiments, the light emitting device is a light emitting diode.

In some embodiments, the light emitting device is a surface mountable device.

Another aspect of the present invention provides a method of using a circuit board assembly of the type having a connector mounted on a first side of a circuit board, a light emitting device mounted on a second side of said circuit board, wherein said light emitting device is in optical communication with an interior of said connector. The method comprising steps of: installing said printed circuit board assembly in a network device; powering said light emitting device for transmitting light through said light transfer passage into said interior region and through said light transmissible plug to a region external to said first opening of said connector; providing a light transmissible plug; and extending said light transmissible plug into said interior region to be operatively engaged with said connector.

Still another aspect of the present invention provides a method repairing a circuit board assembly of the type having a connector mounted on a first side of a circuit board, a light emitting device mounted on a second side of said circuit board, wherein said light emitting device is in optical communication with an interior of said connector, the method comprising steps of: detecting said light emitting device to be faulty; replacing said light emitting device, while maintaining said connector in position on said printed circuit board.

### BRIEF DESCRIPTION OF THE DRAWINGS

Further features and advantages of the present invention will become apparent from the following detailed description, taken in combination with the appended drawings, in which:

FIG. 1 is a schematic illustration showing a prior art connector arrangement using a light pipe;

FIG. 2 is a schematic illustration showing a prior art connector arrangement using an adjacent mounted LED;

FIG. 3A is an exemplary illustration of an embodiment of the present invention with a plug inserted;

FIG. 3B is an exemplary illustration of an embodiment of the present invention with no plug inserted;

FIG. 3C is an exemplary illustration of an embodiment of the present invention with a different LED form factor;

FIG. 3D is an exemplary illustration of an embodiment of the present invention having a light transmissible portion of the circuit board providing optical communication between the LED and the connector;

FIG. 3E is an exemplary illustration of an embodiment of the present invention having a light pipe providing optical communication between the LED and the connector;

FIG. 4 is an exemplary flowchart of an embodiment of the manufacturing aspect of the method of preparing of the present invention;

FIG. 5 is an exemplary flowchart of an embodiment of the using aspect of the method of preparing of the present invention; and

FIG. 6 is an exemplary flowchart of an embodiment of the repairing aspect of the method of preparing of the present invention.

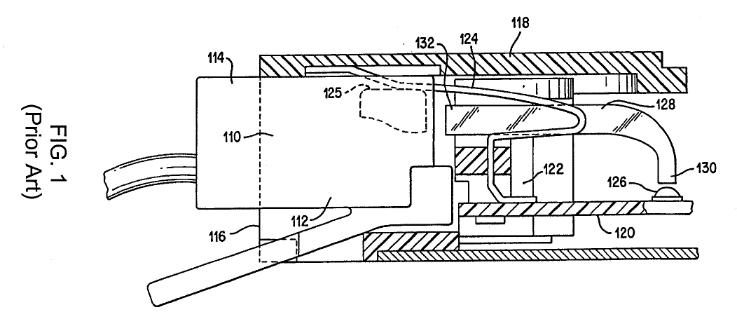

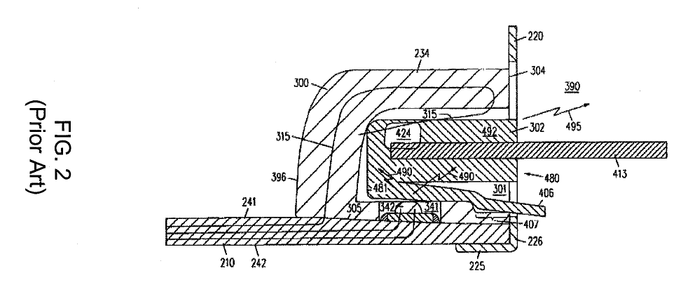

It will be noted that throughout the appended drawings, like features are identified by like reference numerals.

### DETAILED DESCRIPTION OF THE PREFERRED EMBODIMENT

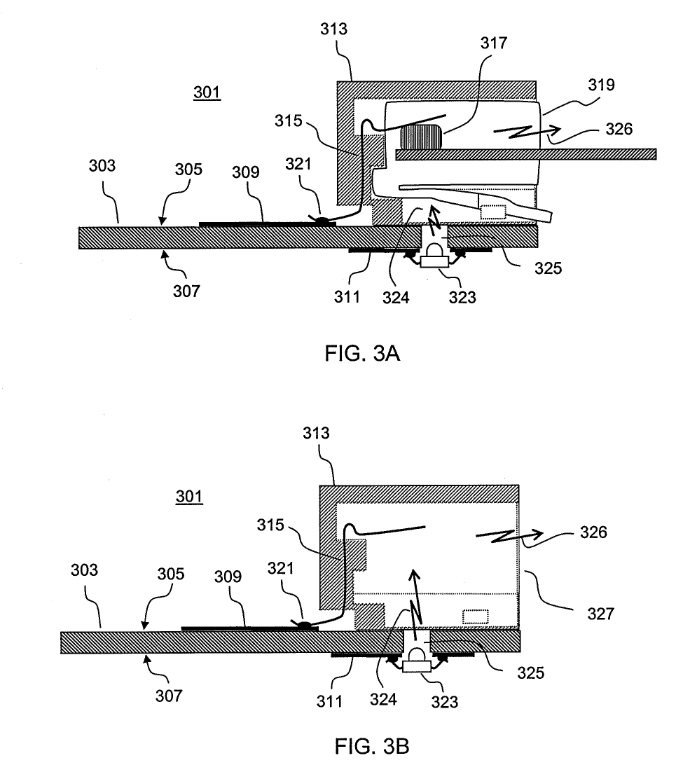

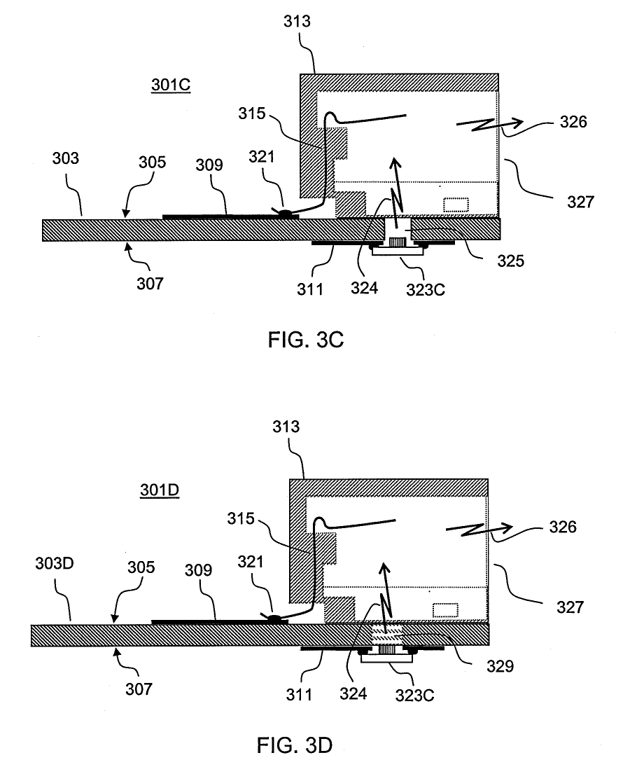

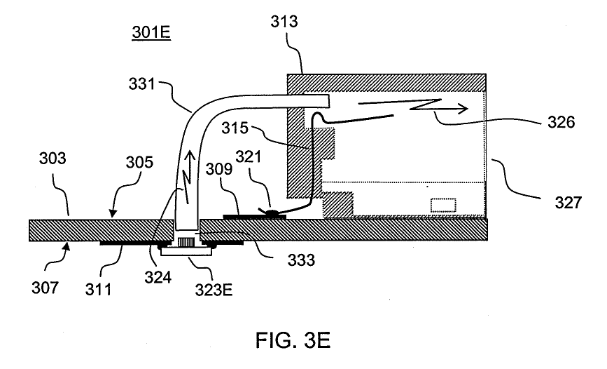

FIG. 3 illustrates an exemplary embodiment of the present invention. A circuit board assembly 301 comprises a printed circuit board 303 having a first (top) side 305 and a second (bottom) side 307. The circuit board 303 as a wiring patterns 309, 311 providing electrical connection between various components. A modular connector 313 is mounted on the top surface 305. The modular connector 313 has electrical contacts 315 to provide resilient connection with corresponding contacts 317 on modular plug 319. Electrical contacts 315 are soldered to wiring pattern 309 at 321 using a wave soldering technique. Light emitting diode (LED) 323 is mounted on the bottom side 307 of the circuit board 303 such that the light emitting portion is facing the circuit board and is capable of projecting light 324 through hole 325, into the interior of the connector 313 to illuminate the interior and transparent plug 319 such that light 326 is visible external of the connector 313. If plug 319 is transparent, translucent or otherwise light transmissible, then light can be visible from the connector 313 even when the plug 319 completely fills opening 327 (in FIG. 3B) of connector 313.

Through-hole 325 provides a light transfer passage through the circuit board 303 to ensure optical communication between the LED 323 and the interior of connector 313. Various other forms of light transfer passages could be used as well, such as a slot in the circuit board or alternatively, providing a transparent or otherwise light transmissible portion in the circuit board.

In a preferred embodiment the LED 323 is provided in a surface mount package and is mounted to the wiring pattern 311 using surface mount technology using a reflow soldering process such as infrared reflow or vapor phase soldering technique. Other methods of providing electrical connection between the LED and the wiring pattern are also well within the scope of the present invention. Other type of light emitting devices are also contemplated and would be apparent to persons skilled in the art.

As shown in FIG. 3B, light from LED 323 is also visible external to opening 327 when there is no plug inserted into the connector and opening 327 is uncovered, light 324 from LED 323 can reflect off of interior surfaces of the connector 313 and portions of the circuit board 303 exposed to the interior of connector 313, and thereby be visible 326 external to the opening 327 of the connector 313. In this scenario, LED 323 can be used to indicate a configuration of circuitry associated with the connector. LED 323 can be a single LED, dual LED having dual emitters integrated in a single package, or alternatively, LED 323 can represent multiple LEDs to provide multiple colors of light to provide indications of different configurations, conditions or status.

An example of displaying a circuit configuration indication would be where the circuit board assembly is part of a configurable private branch exchange (PBX) and connector 313 can provide connection for a FXO connection or FXS connection. LED 323 can provide a green signal to indicate that the circuitry associated with connector 313 is configured as a FXO, to connect to telephones and alternatively can provide a red signal to indicate that the circuitry associated with connector 313 is configured as a FXS, to connect to external telephone line connections.

One advantage of the illustrated embodiment is that LED 323 remains accessible so that if LED 323 should fail or be found defective, it can easily be removed and replaced without having to remove connector 313.

FIG. 3C illustrates an alternative embodiment of the present invention showing a chip style surface mount package for LED 323C.

It is contemplated to use other types of light emitting devices in addition to LEDs, such as for example, incandescent lamps and other light sources suitable for mounting on a printed circuit board.

FIG. 3D illustrates another embodiment of the present invention where the LED 323C is in optical communication with the interior of the connector 313 via a light transmissible portion 329 of the circuit board 303D. The light transmissible portion 329 is devoid of circuit traces, wiring patterns, paint or other opaque features such that light from the LED 323C can traverse the light transmissible portion 329 to illuminate the interior of the connector 313. Alternatively, light transmissible portion 329 can be a light pipe or other transparent conduit to direct light from LED 323E to the interior of connector 313.

FIG. 3E illustrates still another embodiment of the present invention, where the LED 323E is in optical communication with the interior of the connector 313 via a light pipe 331. Advantageously, light pipe 331 fits partially into through-hole 333 to improve light transfer from LED 323E and to reduce stray light from LED 323E.

The description of exemplary embodiments shown in FIGS. 3A to 3E show a circuit board assembly having a light emitting device mounted on the bottom side of the circuit board, providing illumination for the interior of the connector to provide an indicator visible to a user viewing the connector.

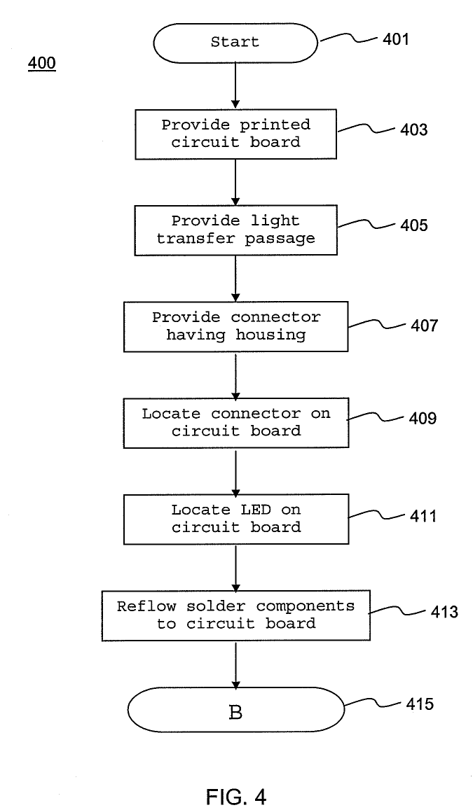

An exemplary manufacturing aspect of the method of the present invention will now be described with reference to FIG. 4. As shown in FIG. 4, the method 400 starts at step 401. At step 403, the method provides a printed circuit board. The circuit board has circuit traces or wiring pattern on a top side to accept a modular jack, circuit traces on the bottom side to accept an LED. At step 405, the method provides a light transfer passage to accommodate light output from the LED directed to the top side. This step can include drilling a through hole at the appropriate location or alternatively, this step can be incorporated into the manufacture of the printed circuit board.

At step 407 the method provides a connector configured to accommodate a plug such as a modular RJ type plug. For example, the 8P8C modular connector is commonly referred to as “RJ45”. It is advantageous for the connector to be a female connector having a first surface having an opening configured to receive a plug and a second surface configured to mount adjacent to a printed circuit board. The second surface being light transmissible either by transparency or by having an opening in the second surface to accept light.

At step 409 the connector is located on the circuit board in preparation for electrical connection. The connector can be mechanically fastened to the circuit board by means of adhesive, snap connection or clips. Alternatively the connector can be held in place by methods well known in the art of surface mount technology such as for example, embedding its circuit board contacts into solder paste applied to the electrical contact pads of the circuit traces on the top side of the circuit board. The connector is positioned in alignment with the light transfer passage.

At step 411 the LED is located on the bottom side of the circuit board in alignment with the light transfer passage and oriented such that when it is activated, it can emit light toward the light transfer passage. The LED can be held in place by methods well known in the art of surface mount technology such as for example, embedding its circuit board contacts into solder paste applied to the electrical contact pads of the circuit traces on the bottom side of the circuit board.

At step 413 of the circuit board with the components in place, is subjected to a reflow solder process as is well known in the art. In one embodiment, the circuit board is passed through a conveyorized reflow oven such as an infrared reflow solder oven or a vapor phase solder oven. The reflow solder process can comprise one pass to solder the components on both sides of the circuit board or alternatively a two pass process in which each pass solders components on the one side of the circuit board at a time.

The manufacturing aspect of the embodiment of the present invention terminates at step 415 (“B”).

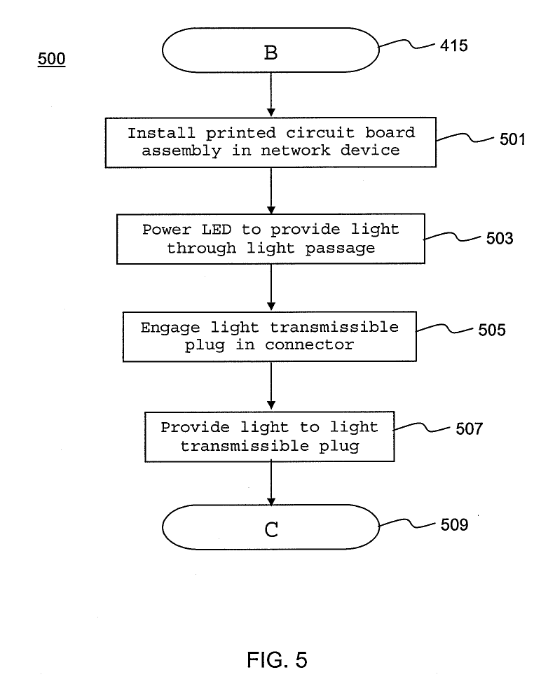

An exemplary method of a using 500 of the present invention is illustrated in FIG. 5. For illustrative purposes, the process continues from step 415 (“B”), thus the process starts at step 501 where the circuit board assembly is installed in a network device or other electronic device such as a computer interfacing device. At step 503 the LED on the bottom side of the circuit board is powered to provide light. The light can be red, green, yellow, blue, and continuous or intermittent as required. In some embodiments multiple LEDs are provided in which case one or more of the multiple LEDs can be powered as required. The LED is oriented to direct light through the light transfer passage and toward the interior of the connector, thus illuminating the interior of the connector, the light being visible from a position external to the opening of the connector. At step 505 a light transmissible plug is inserted into the connector so as to be operably engaged with the connector. At step 507 the light entering the interior of the connector from the LED illuminates the light transmissible plug, the light being visible external to the connector Method 500 terminates at step 509 (“C”).

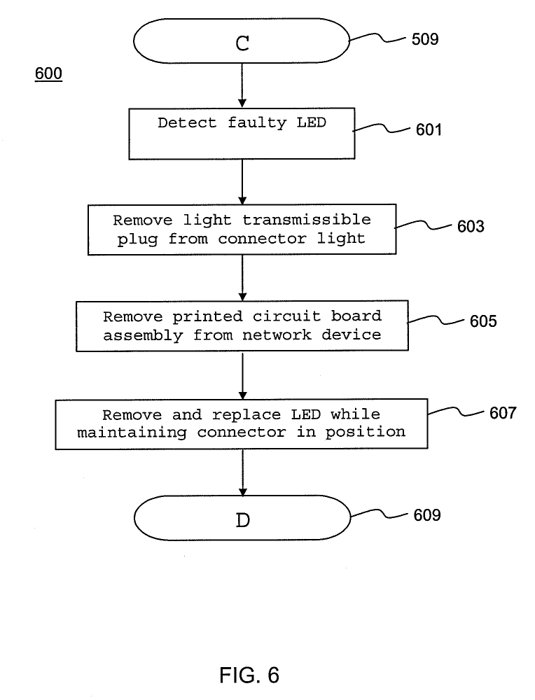

FIG. 6 illustrates a flowchart of an exemplary embodiment of a repairing method 600 of preparing of the present invention. For illustrative purposes, the method follows from step 509 (“C”) where the circuit board assembly is in use. Thus the repair process starts at step 601 where a faulty LED is detected. At step 603, the light transmissible plug is removed from the connector and at step 605, the circuit board assembly is removed from the network device. At step 607, the LED is removed from the bottom side of the printed circuit board. The LED is easily accessible because it is mounted on the bottom side of the connector and is therefore not obstructed by the connector mounted on the top side of the circuit board. In a preferred embodiment, the LED is a surface mount device (SMD) and as such, it is relatively easy to remove and replace it because it does not have leads extending through holes on the circuit board. Heating the surface mount solder connections melts the solder and permits removal of the SMD LED as is well known to those skilled in the art. The repair process terminates at step 609 (“D”), at which point the circuit board assembly can be put into service.

In an other embodiment, steps 603 and step 605 would be superfluous for example, where step 601 flows from a manufacturing process test step, or where the circuit board has already been removed from the network device.

The embodiment(s) of the invention described above is(are) intended to be exemplary only. The scope of the invention is therefore intended to be limited solely by the scope of the appended claims.

1. A method of preparing a circuit board assembly, said method comprising steps of:
providing a printed circuit board having first and second opposed surfaces;
providing a light transfer passage in said printed circuit board to extend between said first and second opposed surfaces;
providing a connector having a housing, said housing having an interior region in communication with a first opening, said opening configured to accept a plug;
locating said connector on said first opposed surface, such that said light transfer passage is in optical communication with said interior region via a second opening in the connector side that is adjacent to said first side of said circuit board; locating a light emitting device on said second opposed surface, such that said light emitting device is oriented to project light through said light transfer passage and said second opening into said interior region; and
subjecting said printed circuit board to a reflow soldering process to operatively mount said light emitting device and said connector to said printed circuit board.

2. A method as claimed in claim 1, wherein said step of reflow soldering comprises infrared reflow soldering.

3. A method as claimed in claim 1, wherein said step of reflow soldering comprises vapor phase soldering.

4. A method as claimed in claim 1, wherein said light emitting device comprises a light emitting diode.

5. A method as claimed in claim 1, wherein said light emitting device comprises a surface mountable device.

6. A method of using a circuit board assembly of the type having a connector mounted on a first side of a circuit board, a light emitting device mounted on a second side of said circuit board, wherein said light emitting device is in optical communication with an interior of said connector, the method comprising steps of:
installing said printed circuit board assembly in a network device;
powering said light emitting device for transmitting light through said light transfer passage into said interior region and through said light transmissible plug to a region external to said first opening of said connector;
providing a light transmissible plug; and
extending said light transmissible plug into said interior region to be operatively engaged with said connector.

7. A method of repairing a circuit board assembly of the type having a connector mounted on a first side of a circuit board, a light emitting device mounted on a second side of said circuit board, wherein said light emitting device is in optical communication with an interior of said connector, the method comprising steps of:
detecting said light emitting device to be faulty; and
replacing said light emitting device, while maintaining said connector in position on said printed circuit board.

8. A method as claimed in claim 1, wherein said light emitting device comprises a plurality of light emitting diodes.

9. A method as claimed in claim 8, wherein said plurality of light emitting diodes comprises red and green light emitting diodes.
